(19) United States
(12) Patent Application Publication
(10) Pub. No.: US 2017/0033100 A1
(43) Pub. Date: Feb. 2, 2017

(54) MEMORY DEVICE AND FABRICATING METHOD THEREOF

(71) Applicant: Inotera Memories, Inc., Taoyuan City (TW)

(72) Inventor: Tieh-Chiang WU, Taoyuan City (TW)

(21) Appl. No.: 14/814,459

(22) Filed: Jul. 30, 2015

(51) Int. Cl. H01L 27/088; H01L 23/528; H01L 27/105; H01L 29/423; H01L 21/8234; H01L 21/768; H01L 23/532

(52) U.S. Cl. CPC H01L 27/088; H01L 21/76834; H01L 23/528; H01L 23/53214; H01L 23/53261; H01L 23/53257; H01L 29/4238; H01L 29/4236; H01L 21/823475; H01L 27/1052

(57) ABSTRACT

A memory device and a method for fabricating thereof are provided. The memory device includes a substrate, a first active region, a second active region, a gate structure, and a contact structure. The first active region and the second active region are alternately disposed in the substrate. The gate structure is disposed in the substrate and between the first active region and the second active region. The contact structure is over the substrate and electrically connected to one of the first active region and the second active region. The contact structure includes a metal portion directly in contact with one of the first active region and the second active region.

### BACKGROUND

### Description of Related Art

As the evolution in the manufacturing technology of the semiconductor devices, the functional density of the semiconductor devices has increased with the decrease of device sizes to achieve higher integration density of the semiconductor devices. For instance, continuous efforts have been made to reduce the sizes of transistors for memory devices in order to increase component density and improve overall performance of the memory devices. However, as the reduced transistor size, the junction contact resistance thereof is increased. The performance of the memory device is thus degraded due to the high junction contact resistance.

Accordingly, an improved memory device and a fabricating method thereof are required.

### SUMMARY

An aspect of the present disclosure provides a memory device. The memory device includes a substrate, a first active region, a second active region, a gate structure, and a contact structure. The first active region and the second active region are alternately disposed in the substrate. The gate structure is disposed in the substrate and between the first active region and the second active region. The contact structure is over the substrate and electrically connected to one of the first active region and the second active region. The contact structure includes a metal portion directly in contact with one of the first active region and the second active region.

In various embodiments of the present disclosure, the gate structure is a single-layer structure or a multi-layer structure.

In various embodiments of the present disclosure, the gate structure is a multi-layer structure including a first portion and a second portion embedded in the first portion.

In various embodiments of the present disclosure, the metal portion of the contact structure comprises one or more metal layers.

In various embodiments of the present disclosure, the metal portion of the contact structure includes a first metal layer and a second metal layer. The first metal layer is directly in contact with one of the first active region and the second active region, and the second metal layer is embedded in the first metal layer.

In various embodiments of the present disclosure, a bottom surface of the contact structure is lower than a top surface of the substrate.

In various embodiments of the present disclosure, the contact structure further includes a dielectric portion over the metal portion.

In various embodiments of the present disclosure, the memory device further includes a gate dielectric layer disposed between the gate structure and the first active region and between the gate structure and the second active region.

In various embodiments of the present disclosure, the memory device further includes a spacer layer covering the contact structure.

Another aspect of the present disclosure provides method for fabricating a memory device, and the method includes following steps. A first active region and a second active region are alternately formed in a substrate. A gate structure is formed in the substrate and between the first active region and the second active region. A contact structure including a metal portion is formed over the substrate, and the metal portion is directly in contact with one of the first active region and the second active region.

In various embodiments of the present disclosure, forming the gate structure includes forming a first portion, and forming a second portion embedded in the first portion.

In various embodiments of the present disclosure, forming the contact structure including the metal portion includes forming one or more metal layers.

In various embodiments of the present disclosure, forming the contact structure including the metal portion includes depositing a first metal layer over the substrate. A second metal layer is embedded in the first metal layer.

In various embodiments of the present disclosure, forming the contact structure further includes depositing a dielectric portion over the metal portion.

In various embodiments of the present disclosure, the method further includes forming a gate dielectric layer between the gate structure and the first active region and between the gate structure and the second active region.

In various embodiments of the present disclosure, the method further includes depositing a spacer layer covering the contact structure.

In various embodiments of the present disclosure, fabricating the memory device is to fabricate the memory device with a first region and a second region.

In various embodiments of the present disclosure, forming the first active region, the second active region, the gate structure, and the contact structure are performed in the first region.

In various embodiments of the present disclosure, the method further includes forming a peripheral gate stack over the substrate in the second region simultaneously with forming the contact structure in the first region.

In various embodiments of the present disclosure, the first region is a memory cell array region, and the second region is a peripheral circuit region.

These and other features, aspects, and advantages of the present disclosure will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

The disclosure could be more fully understood by reading the following detailed description of the embodiment, with reference made to the accompanying drawings as follows:

FIG. 1 is a cross-sectional view of a memory device in accordance with various embodiments of the present disclosure; and

FIGS. 2A through 7B are cross-sectional views at various stages of fabricating a memory device in accordance with various embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The following embodiments are disclosed with accompanying diagrams for detailed description. For illustration clarity, many details of practice are explained in the following descriptions. However, it should be understood that these details of practice do not intend to limit the present invention. That is, these details of practice are not necessary in parts of embodiments of the present invention. Furthermore, for simplifying the drawings, some of the conventional structures and elements are shown with schematic illustrations.

As aforementioned problems, the performance of the memory cell is affected by junction contact resistance, especially contact resistance variation. The contact resistance variation is related to the material of the contact. Particularly, polysilicon is commonly used in the contact of a general memory device, and is disposed between an active region and a metal material of the contact. However, the resistance of polysilicon is high, which inevitably degrade the performance of the memory device.

The present disclosure provides a memory device and a fabricating method thereof. The memory device of the present disclosure applies a buried contact structure, and a metal portion of which is directly in contact with an active region without using polysilicon. Therefore, the resistance can be reduced, and thereby improving the performance of the memory device. Further, the method for fabricating the memory device of the present disclosure integrates processes of forming the contact structure and the peripheral gate stack to provide a simpler process flow.

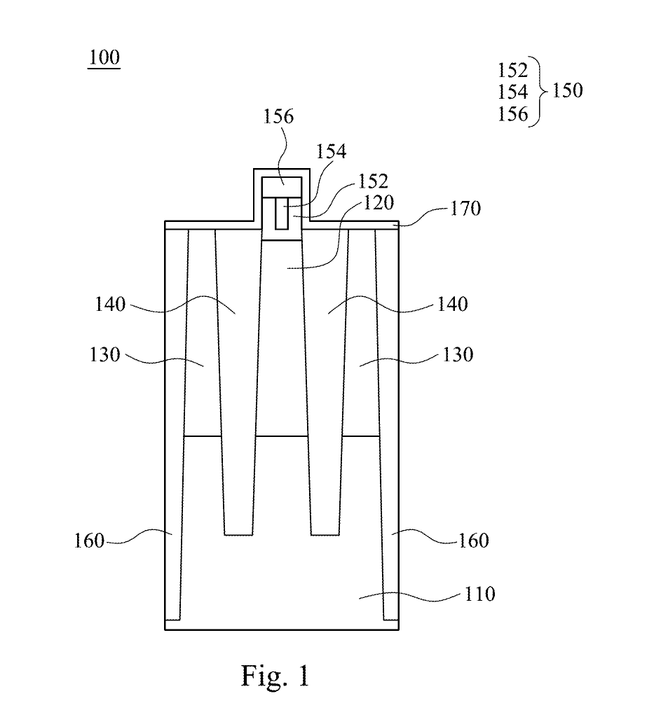

Referring to FIG. 1, FIG. 1 is a cross-sectional view of a memory device 100 in accordance with various embodiments of the present disclosure. The memory device 100 includes a substrate 110, a first active region 120, second active regions 130, gate structures 140, a contact structure 150, isolation structures 160, and a spacer layer 170. The first active region 120 and the second active regions 130 are alternately disposed in the substrate 110. The gate structures 140 are disposed in the substrate 110 and between the first active region 120 and the second active regions 130. The contact structure 150 is over the substrate 110 and electrically connected to the first active region 120. The contact structure 150 includes a metal portion and a dielectric portion 156. The metal portion is directly in contact with the first active region 120. The isolation structures 160 are disposed in the substrate 110, and the first active region 120, the second active regions 130, and the gate structures 140 are disposed between two of the isolation structures 160. The spacer layer 170 covers the contact structure 150.

The substrate 110 may be a silicon substrate, a silicon/germanium (SiGe) substrate, an epi-substrate, a silicon-on-insulator (SOI) substrate, etc.

The first active region 120 and the second active region 130 may be doped regions in the substrate 110, and respectively function as a source and a drain of the memory device 100, or vice versa. The first active region 120 and the second active region 130 may be n-doped or p-doped, depending on actual requirements.

It is noteworthy that the gate structures 140 are disposed in the substrate 110, and thus the memory device 100 in the abovementioned embodiments can be called as a recess access device (RAD). When a bias is applied to the gate structure 140, a channel may be formed in the substrate 110 and around the gate structure 140. Current may flow between the first active region 120 and the second active region 130 through the channel.

The memory device may applies a dual gate system, which a memory cell of the memory device includes two gate structures, one first active region, and two second active regions. An isolation structure is disposed between two adjacent memory cells. The first active region is between the gate structures, and the second active regions are between the gate structures and the isolation structures.

The metal portion of the contact structure 150 may be a single-layer structure or a multi-layer structure, i.e. the metal portion includes one or more metal layers. In some embodiments, the metal portion of the contact structure 150 includes a first metal layer 152 and a second metal layer 154 as shown in FIG. 1. The first metal layer 152 is directly in contact with the first active region 120; and the second metal layer 154 is embedded in the first metal layer 152.

The first metal layer 152 and the second metal layer 154 of the contact structure 150 may be made of tungsten (W), titanium nitride (TiN), tantalum nitride (TaN), tungsten nitride (WN), ruthenium (Ru), molybdenum nitride (MoN), TaN/TiN, WN/TiN, arsenic (As) doped polycrystalline silicon, tantalum (Ta), aluminum (Al), titanium (Ti), zirconium nitride (ZrN), or a combination thereof. The first metal layer 152 may be made of a material with high resistance, such as silicon-containing material, oxide, or nitride, as a barrier. The second metal layer 154 may be made of a material with low resistance considering conductivity. In some embodiments, the first metal layer 152 is made of titanium nitride, and the second metal layer 154 is made of tungsten.

It is noteworthy that a bottom surface of the contact structure 150 is possible lower than a top surface of the substrate 110 as shown in FIG. 1. That is, a part of the contact structure 150 is buried in the substrate 110.

In some embodiments, the isolation structures 160 are shallow trench isolation (STI) structures. The isolation structures 160 may be disposed in the substrate 110 and between two adjacent memory cells (not shown) to provide electrical isolation. In some embodiments, the isolation structures 160 are made of dielectric materials, such as silicon oxide or other suitable materials.

The memory device of the present disclosure applies a novel contact structure, which the metal portion of the contact structure is directly in contact with one of the first active region and the second active region, and there is no polysilicon therebetween. As a result, the resistance of the contact structure can be reduced, and thereby improving the performance of the memory device.

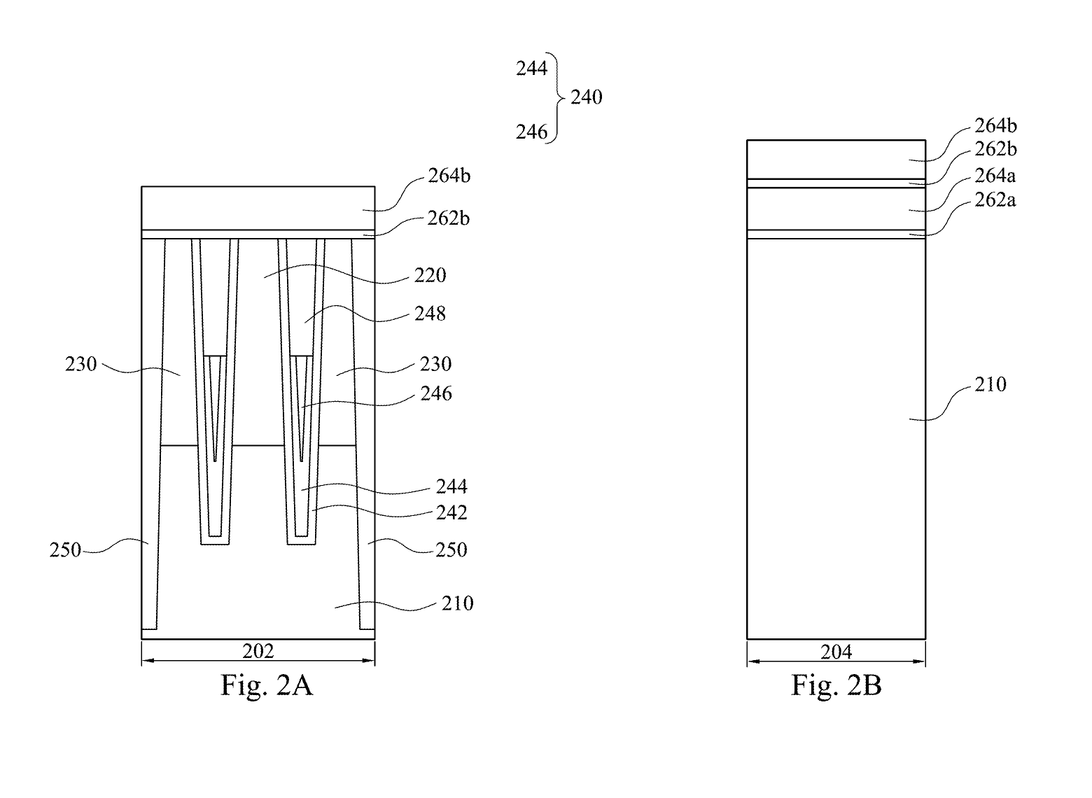

FIGS. 2A through 7B are cross-sectional views at various stages of fabricating a memory device 200 with a first region 202 and a second region 204 in accordance with various embodiments of the present disclosure. In some embodiments, the first region 202 is a memory cell array region, and the second region 204 is a peripheral circuit region of the memory device 200.

Referring to FIGS. 2A and 2B, which respectively show an intermediate stage of fabricating the memory device 200 in the first region 202 and the second region 204, a substrate 210 is first provided for the fabrication of the memory device 200. A first active region 220 and second active regions 230 are formed alternately in the substrate 210 in the first region 202, and gate structures 240 are formed in the substrate 210 in the first region 202 and between the first active region 220 and the second active regions 230. Isolation structures 250, which may be shallow trench isolation (STI) structures, are formed in the substrate 210, and the first active region 220, the second active regions 230, and the gate structures 240 are disposed between two of the isolation structures 250. In some embodiments, the isolation structures 160 are made of dielectric materials, such as silicon oxide or other suitable materials.

A first oxide layer 262a and a first polysilicon layer 264a are deposited over the substrate 210 in the second region 204. Then, a second oxide layer 262b and a second polysilicon layer 264b are deposited over the substrate 210 in the first region 202 and the first polysilicon layer 264a in the second region 214.

The substrate 210 may be any suitable substrate, and the specific features of the substrate 210 may be referred to those exemplified for the substrate 110 of FIG. 1.

The first active region 220 and the second active regions 230 may be formed by doping, such as n-doping or p-doping, depending on actual requirements. The first active region 220 and the second active region 230 may respectively function as a source and a drain of the memory device, or vice versa. The first active region 220 and the second active regions 230 may be formed before or after the gate structures 240.

The gate structure 240 may be a single-layer structure or a multi-layer structure. For instance, the gate structure 240 includes a first portion 244 and a second portion 246 embedded in the first portion 244 as shown in FIG. 2A.

In some embodiments, a gate dielectric layer 242 is formed between the gate structure and the first active region and between the gate structure and the second active region. The gate dielectric layer 242 may be formed by deposition before forming the gate structure 240. The material of the gate dielectric layer 242 may be any suitable dielectric material, such as oxide. In some embodiments, a dielectric layer 248 is disposed on the gate structure 240, and may be made of oxide or nitride.

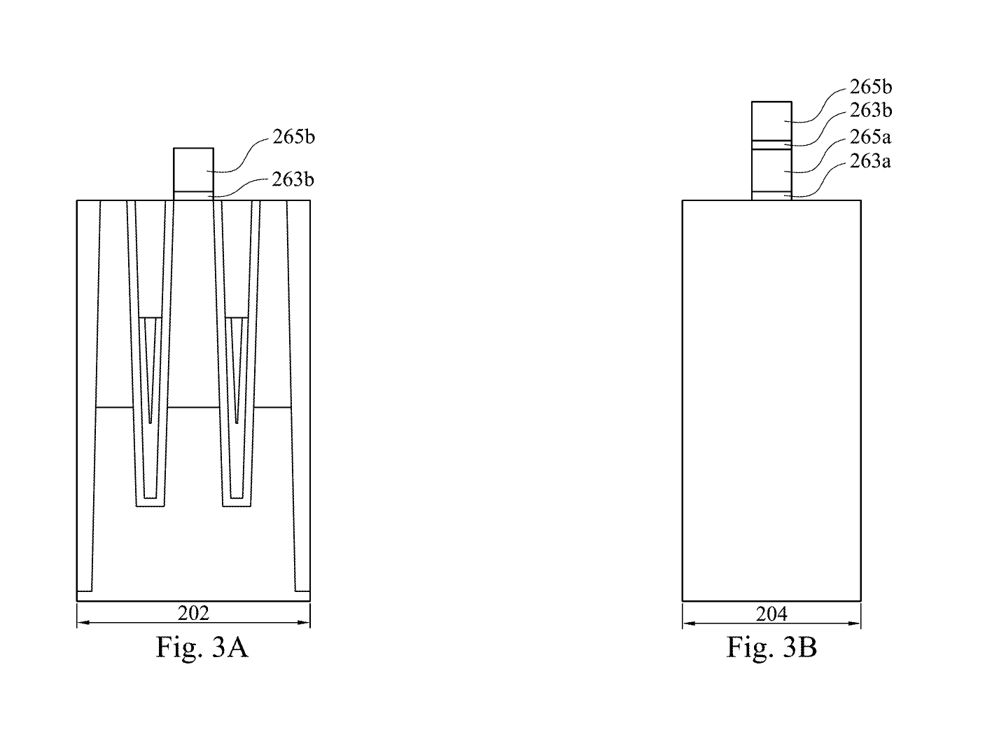

Continuing in FIGS. 3A and 3B, parts of the second oxide layer 262b and the second polysilicon layer 264b are removed in the first region 202 to form a second oxide portion 263b and a second polysilicon portion 265b, respectively. Further, parts of the first oxide layer 262a, the first polysilicon layer 264a, the second oxide layer 262b, and the second polysilicon layer 264b are removed in the second region 204 to form a first oxide portion 263a, a first polysilicon portion 265a, a second oxide portion 263b, and a second polysilicon portion 265b, respectively. The abovementioned removing may be performed by a photolithography process.

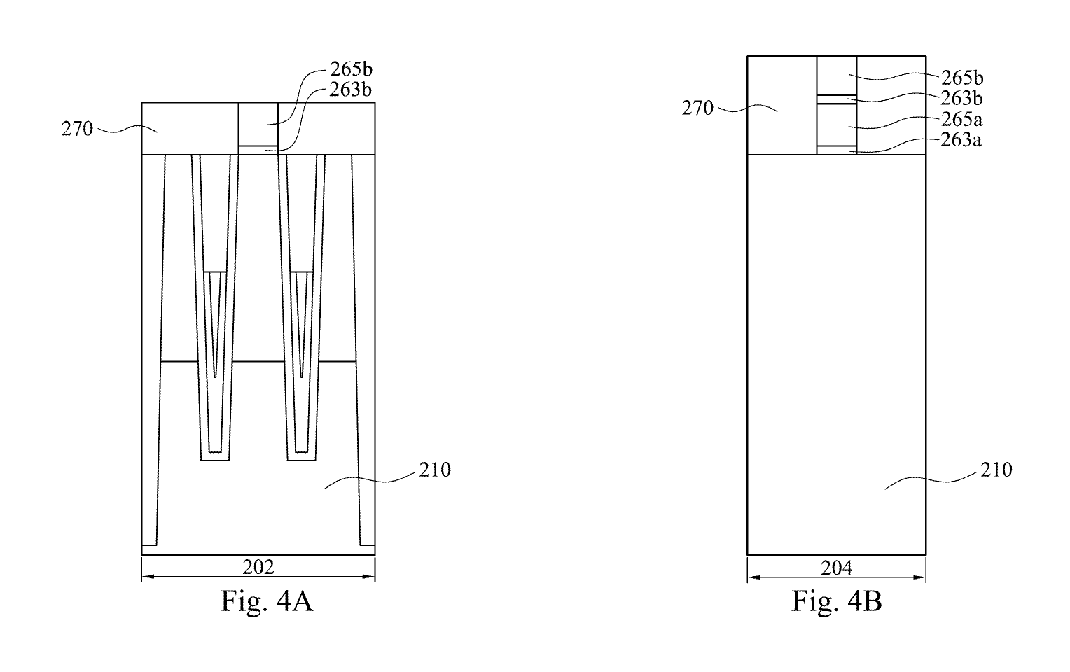

Referring to FIGS. 4A and 4B, a dielectric layer 270 is deposited over the substrate 210 and surrounding the second oxide portion 263b and the second polysilicon portion 265b in the first region 202. Also, the dielectric layer 270 is deposited over the substrate 210 and surrounding the first oxide portion 263a, the first polysilicon portion 265a, the second oxide portion 263b, and the second polysilicon portion 265b in the second region 204. The material of the dielectric layer 270 may be oxide, nitride, or a combination thereof. The dielectric layer 270 may be formed by any suitable deposition process. Examples of the deposition process include but are not limited to chemical vapor deposition (CVD), physical vapor deposition (PVD), atomic layer deposition (ALD), and a combination thereof. A chemical mechanical planarization (CMP) process may be optionally performed after the deposition.

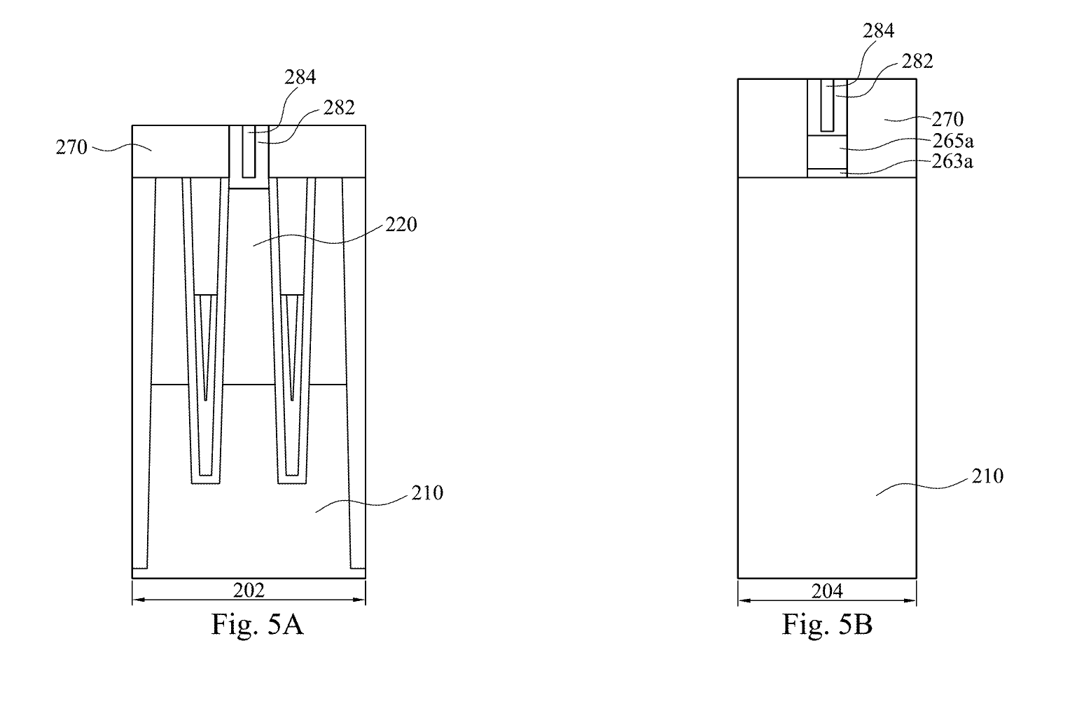

Continuing in FIGS. 5A and 5B, the second oxide portion 263b and the second polysilicon portion 265b in the first region 202 and the second region 204 are removed to expose a part of the substrate 210 in the first region 202 and the first polysilicon portion 265a in the second region 204. The second polysilicon portion 265b may be removed by stripping, and the second oxide portion 263b may be removed by etching. Then, a first metal layer 282 and a second metal layer 284 are deposited over the exposed part of the substrate 210 in the first region 202 and the first polysilicon portion 265a in the second region 204. The formed second metal layer 284 is embedded in the first metal layer 282. The first metal layer 282 and the second metal layer 284 in the first region 202 would be a metal portion of a contact structure formed in the subsequent process. The first metal layer 282 and the second metal layer 284 may be deposited by any deposition process exemplified above. In some embodiments, a CMP process is performed after the deposition.

Examples of the material of the first metal layer 282 and the second metal layer 284 include, but are not limited to tungsten (W), titanium nitride (TiN), tantalum nitride (TaN), tungsten nitride (WN), ruthenium (Ru), molybdenum nitride (MoN), TaN/TiN, WN/TiN, arsenic (As) doped polycrystalline silicon, tantalum (Ta), aluminum (Al), titanium (Ti), zirconium nitride (ZrN), or a combination thereof. In some embodiments, the first metal layer 282 is made of titanium nitride, and the second metal layer 284 is made of tungsten.

It is noteworthy that a part of the first active region 220 in the substrate 210 in the first region 202 is also removed along with the etching of the second oxide portion 263b. Therefore, a part the contact structure formed in the subsequent process is buried in the substrate 210.

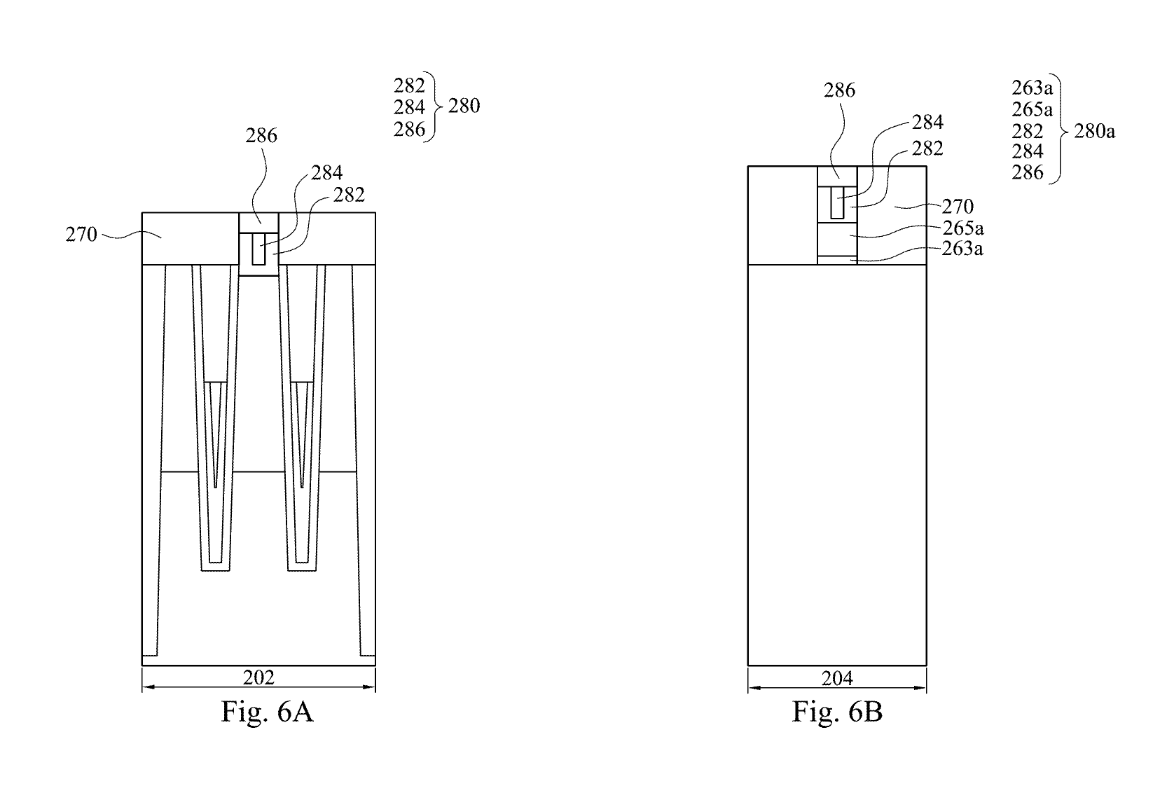

Referring to FIGS. 6A and 6B, the first metal layer 282 and the second metal layer 284 in the first region 202 and the second region 204 are recessed. A dielectric portion 286 is deposited over the first metal layer 282 and the second metal layer 284 in the first region 202 and the second region 204 to form a contact structure 280 in the first region 202 and a peripheral gate stack 280a in the second region 204. A CMP process may be optionally performed after the deposition to level the dielectric portion 286 with the dielectric layer 270. In some embodiments, the material of the dielectric portion 286 is silicon nitride (SiN).

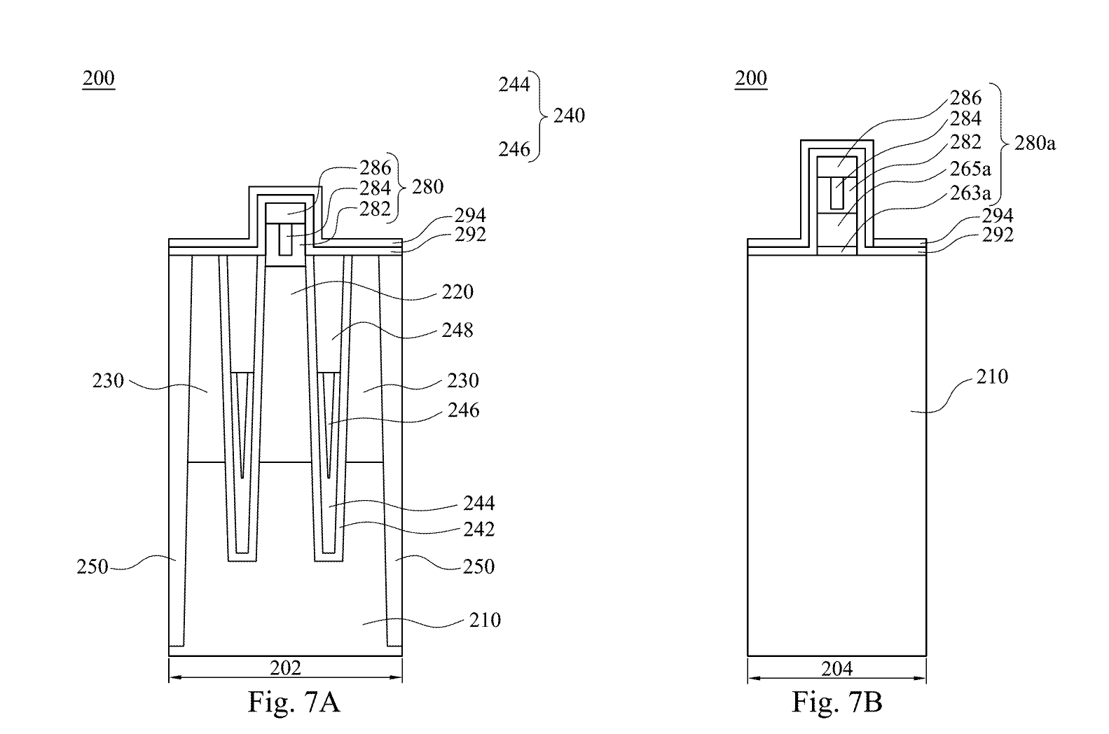

Continuing in FIGS. 7A and 7B, the dielectric layer 270 is removed in first region 202 and the second region 204. The dielectric layer 270 may be removed by stripping. Then, a first spacer layer 292 and the second spacer layer 294 are deposited covering the contact structure 280 and the peripheral gate stack 280a. The memory device 200 with the first region 202 and the second region 204 is thus formed. In some embodiments, the material of the first spacer layer 292 is oxide, and the material of the second spacer layer 294 is silicon nitride (SiN).

It is noteworthy that the foregoing operating sequences for the method fabricating the memory device are merely examples and are not intended to be limiting, and various changes, substitutions, and alterations may be made without departing from the spirit and scope of the present disclosure. As a result, the resistance of the contact structure can be reduced. Further, the method for fabricating the memory device of the present disclosure forms the contact structure including the metal portion directly in contact with one of the first active region and the second active region. Further, the process for forming the contact structure of the method of the present disclosure may be integrated with the process for forming the peripheral gate stack, which is a simpler process flow comparing to conventional methods.

Referring to FIG. 7A, the formed memory device 200 in the first region 202 includes the substrate 210, the first active region 220, the second active regions 230, the gate structures 240, the gate dielectric layer 242, the dielectric layer 248, the isolation structures 250, the contact structure 280, the first spacer layer 292, and the second spacer layer 294. The first active region 220 and the second active regions 230 are alternately disposed in the substrate 210. The gate structures 240 are disposed in the substrate 210 and between the first active region 220 and the second active regions 230, and includes the first portion 244 and the second portion 246 embedded in the first portion 244. The gate dielectric layer 242 is deposited between the gate structure and the first active region and between the gate structure and the second active region. The dielectric layer 248 is disposed on the gate structure 240. The isolation structures 250 are disposed in the substrate 210. The contact structure 280 is over the substrate 210 and electrically connected to the first active region 220. The contact structure 280 includes the first metal layer 282, the second metal layer 284, and the dielectric portion 286. The first metal layer 282 of the metal portion is directly in contact with the first active region 220. The first spacer layer 292 and the second spacer layer 294 cover the contact structure 280.

The embodiments of the present disclosure discussed above have advantages over existing memory devices and processes, and the advantages are summarized below. The method for fabricating the memory device of the present disclosure integrates processes of forming the contact structure and the peripheral gate stack. The present disclosure provides a simpler process flow for fabricating a memory device. Further, the memory device of the present disclosure includes the buried contact structure with the metal portion directly in contact with one of the first active region and the second active region without using polysilicon. As a result, the resistance of the contact structure can be reduced so as to improve the contact resistance uniformity, and thereby improving the performance of the memory device.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A memory device, comprising:
a substrate;
a first active region and a second active region alternately disposed in the substrate;
a gate structure disposed in the substrate and between the first active region and the second active region; and
a contact structure over the substrate and electrically connected to one of the first active region and the second active region, the contact structure comprising a metal portion directly in contact with one of the first active region and the second active region.

2. The memory device of claim 1, wherein the gate structure is a single-layer structure or a multi-layer structure.

3. The memory device of claim 2, wherein the gate structure is a multi-layer structure comprising:
a first portion; and
a second portion embedded in the first portion.

4. The memory device of claim 1, wherein the metal portion of the contact structure comprises one or more metal layers.

5. The memory device of claim 4, wherein the metal portion of the contact structure comprises:
a first metal layer directly in contact with one of the first active region and the second active region; and
a second metal layer embedded in the first metal layer.

6. The memory device of claim 1, wherein a bottom surface of the contact structure is lower than a top surface of the substrate.

7. The memory device of claim 1, wherein the contact structure further comprises a dielectric portion over the metal portion.

8. The memory device of claim 1, further comprising a gate dielectric layer disposed between the gate structure and the first active region and between the gate structure and the second active region.

9. The memory device of claim 1, further comprising a spacer layer covering the contact structure.

10-20. (canceled)
